(19) United States
(12) Patent Application Publication
(10) Pub. No.: US 2008/0042208 A1
(43) Pub. Date: Feb. 21, 2008

(54) TRENCH MOSFET WITH ESD TRENCH CAPACITOR

(75) Inventor: Fwu-Iuan Hshieh, Saratoga, CA (US)

Correspondence Address: HAMRE, SCHUMANN, MUELLER & LARSON, P.C., P.O. BOX 2902, MINNEAPOLIS, MN, 55402-0902, US

(73) Assignee: FORCE MOS TECHNOLOGY CO., LTD.

(21) Appl. No.: 11/749,391

(22) Filed: May 16, 2007

Related U.S. Application Data
(60) Provisional application No. 60/838,066, filed on Aug. 16, 2006.

(51) Int. Cl. H01L 23/60; H01L 21/336

(52) U.S. Cl. 257/360; 438/245; 257/E21.409

(57) ABSTRACT

An electrostatic discharging (ESD) protected metal oxide semiconductor field effect transistor (MOSFET), an epitaxial layer on substrate; a trench gate structure formed in the epitaxial layer; a source region formed in the substrate near the gate structure; a trench capacitor formed underneath gate metal pad in the epitaxial layer connected between the source region and the gate structure, wherein the trench capacitor acts as an ESD improved element for the MOSFET.

### CROSS REFERENCE

The present application claims the priority of U.S. provisional application Ser. No. 60/838,066, which was filed on Aug. 16, 2006.

### FIELD OF THE INVENTION

The present invention relates to an electrostatic discharging (ESD) protected trench MOSFET, and more particularly, to a trench MOSFET that uses a Zener diode and a trench capacitor as ESD improved elements.

### BACKGROUND OF THE INVENTION

Referring to FIG. 1, a cross-sectional schematic diagram of a trench MOSFET is shown. An epitaxial layer 105 is formed on a substrate 100. A plurality of trenches is provided in the epitaxial layer 105, a gate oxide layer 110 is cover on the sidewalls of the trenches and on the surface of the substrate 100. A polysilicon layer 125 is filled in the trenches as the gate structure. N+ doping regions and p+ doping regions in the substrate at both sides of the trenches are formed as the source of the transistor. Metal connections are formed on the trench MOSFET, wherein metal plugs 135 are in contact with the source and gate, and in turns a source metal pad 140 and a gate metal pad 145 are in contact with the metal plugs 135. In the trench MOSFET shown in FIG. 1, there is no additional electrostatic discharging (ESD) protection except parasitic capacitance (between gate and source) built in active cells of trench MOSFET. When ESD occurs, the structure of the transistor may easily be damaged. Referring to FIG. 2, an equivalent circuit diagram of the trench MOSFET of FIG. 1 is shown. At the bottom of transistor 210, there is a body diode 220 (a diode formed from the n+ region and p+ region in FIG. 1). This transistor is not protected from ESD. When ESD occurs in the transistor 210, the channel of the transistor 210 would be damaged if the parasitic capacitance is not high enough to distribute the ESD charge.

Referring to FIG. 3, U.S. Pat. Nos. 6,657,256 and 6,884,683 are taken as examples. On top of a substrate 300, there is an epitaxial layer 305, in which a plurality of trenches is formed. A p-type doping region 320 is formed in the epitaxial layer 305 and a source is formed in the p-type doping region 320 (n+ doping regions at both sides of the trenches). The sidewalls and bottoms of the trenches and the substrate are covered with a gate oxide layer 310 and a polysilicon layer is filled therein to form a gate structure 325. An insulating layer 330 is further covered on top of the gate structure 325. A Zener diode is formed on the gate oxide 310 (made up by doping regions 333, 335 and 337). Finally, a source metal connection 340 and a gate metal connection 345 are connected to the gate structure 325, source and the Zener diode. Referring now to FIG. 4, an equivalent circuit diagram of the trench MOSFET of FIG. 3 is shown. At the bottom of the transistor 410, there is a body diode 420, and the Zener diode is connected between the gate G and the source S. At the bottom of the body diode 420, there is a capacitor 440 (formed from the doping regions 333, 335 and 337 as one electrode plate, the gate oxide layer 310 underneath as the dielectric layer, and the lowest p-type doping region 320 as another electrode plate). The Zener diode 430 combined with the capacitor 440 form an ESD element. When the gate is experiencing over-voltage (exceeding the breakdown voltage of the Zener diode), current will pass to the source via the Zener diode 430 and the capacitor 440, thus achieving ESD protection. However, non-symmetric I-V characteristics shown in FIG. 5 is observed for the prior art. The Higher Igss at negative bias than at positive bias is resulted from channeling effect triggered by a negative gate bias (negative charge formed at the bottom of the p-type region 335) when the oxide underneath the polysilicon layer is a thin oxide layer. More power consumption will be for higher leakage current Igss.

The present invention provides an ESD protected trench MOSFET and fabricating method thereof. A trench capacitor is connected between the gate and the source of the transistor underneath gate metal pad to assist ESD via an electrode plate having a larger area. Moreover, a Zener diode is formed on top of the trench capacitor sandwiched with a thick oxide to avoid the non-symmetric I-V issue. When the gate is experiencing a voltage larger than the breakdown voltage of the Zener diode, ESD current passes to the source via the Zener diode and the trench capacitor, thereby protecting the structure of the trench MOSFET.

### SUMMARY OF THE INVENTION

An electrostatic discharging (ESD) protected metal oxide semiconductor field effect transistor (MOSFET), a substrate; a trench gate structure formed in the epitaxial layer, surrounding with body regions; a source region formed in the epitaxial layer near the gate structure; a trench capacitor formed in the the body regions underneath gate metal pad connected between the source region and the gate structure, wherein the trench capacitor acts as an ESD improved element for the MOSFET.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional schematic diagram of a trench MOSFET;

FIG. 2 is an equivalent circuit diagram of the trench MOSFET shown in FIG. 1;

FIG. 3 is a cross-sectional schematic diagram of a trench MOSFET, wherein a Zener diode and a capacitor are connected between the gate and source as ESD elements;

FIG. 4 is an equivalent circuit diagram of the trench MOSFET shown in FIG. 3;

FIG. 5 is a graph depicting a current-voltage curve of the trench MOSFET shown in FIG. 3;

FIG. 6 is a cross-sectional schematic diagram of a trench MOSFET according to a first embodiment of the present invention;

FIG. 7 is an equivalent circuit diagram of the trench MOSFET shown in FIG. 6;

FIG. 8 is a planar diagram of the trench MOSFET shown in FIG. 6, wherein a plurality of trench capacitors is formed on the semiconductor substrate;

FIG. 9 is a cross-sectional schematic diagram of a trench MOSFET according to a second embodiment of the present invention;

FIG. 10 is a graph depicting a current-voltage curve of the trench MOSFET shown in FIG. 9;

FIGS. 11 to 17 illustrate a process flow for fabricating a trench MOSFET according to a third embodiment of the present invention; and

FIGS. 18 to 24 illustrate a process flow for fabricating a trench MOSFET according to a fourth embodiment of the present invention.

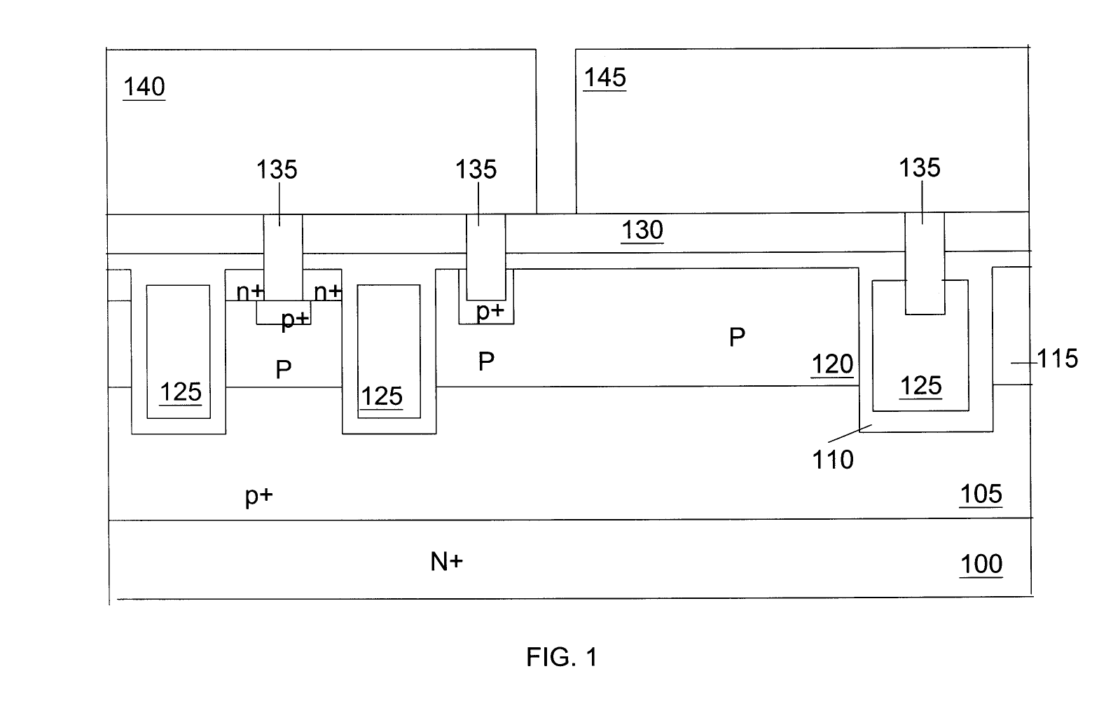

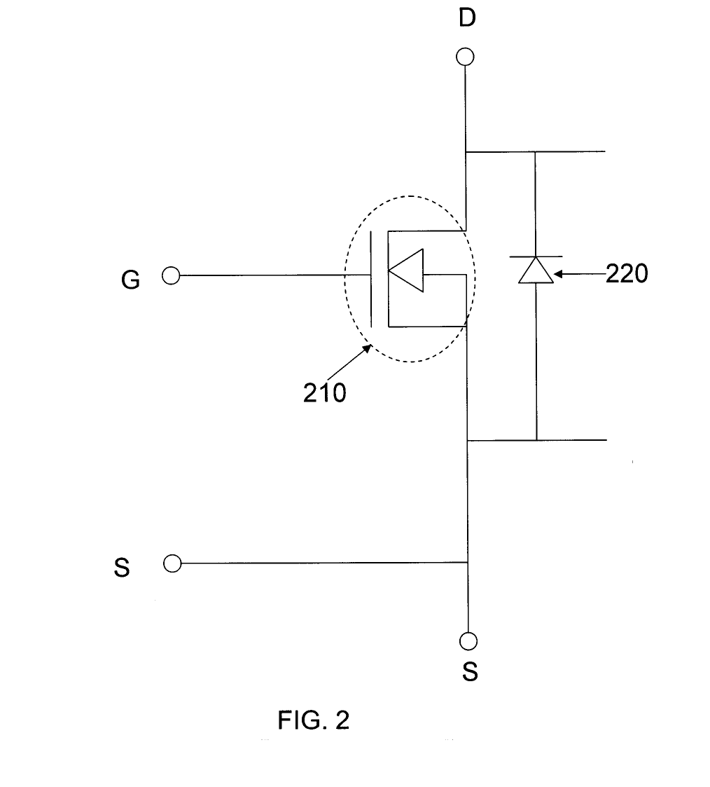

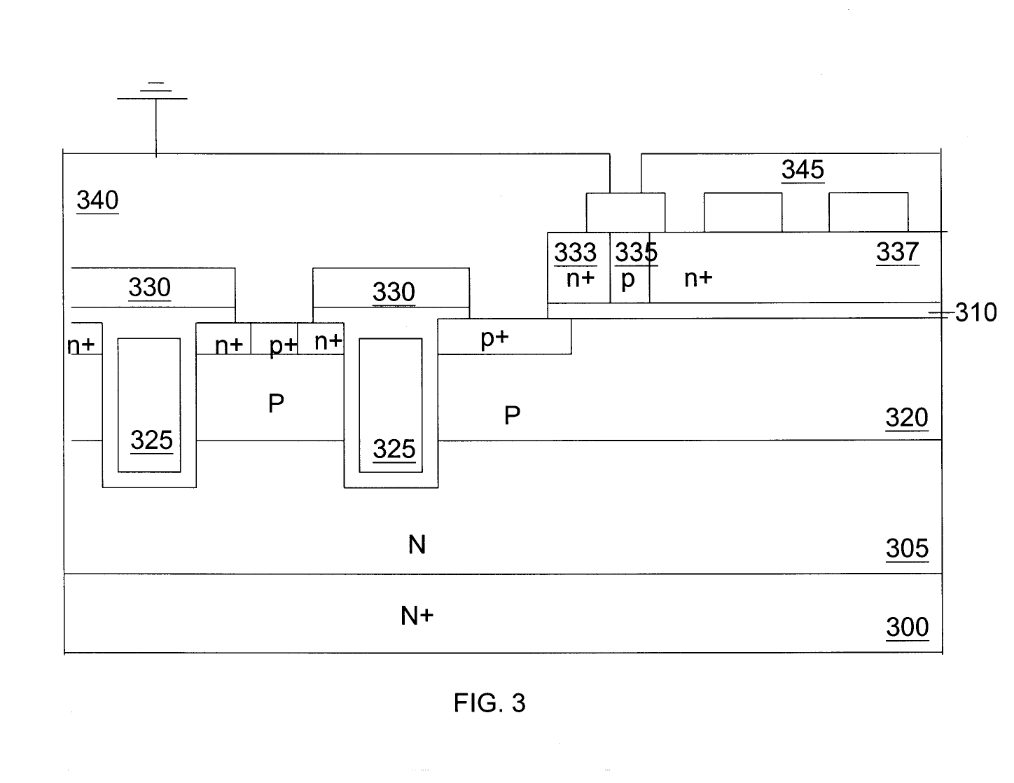

### DETAILED DESCRIPTION OF THE EMBODIMENTS

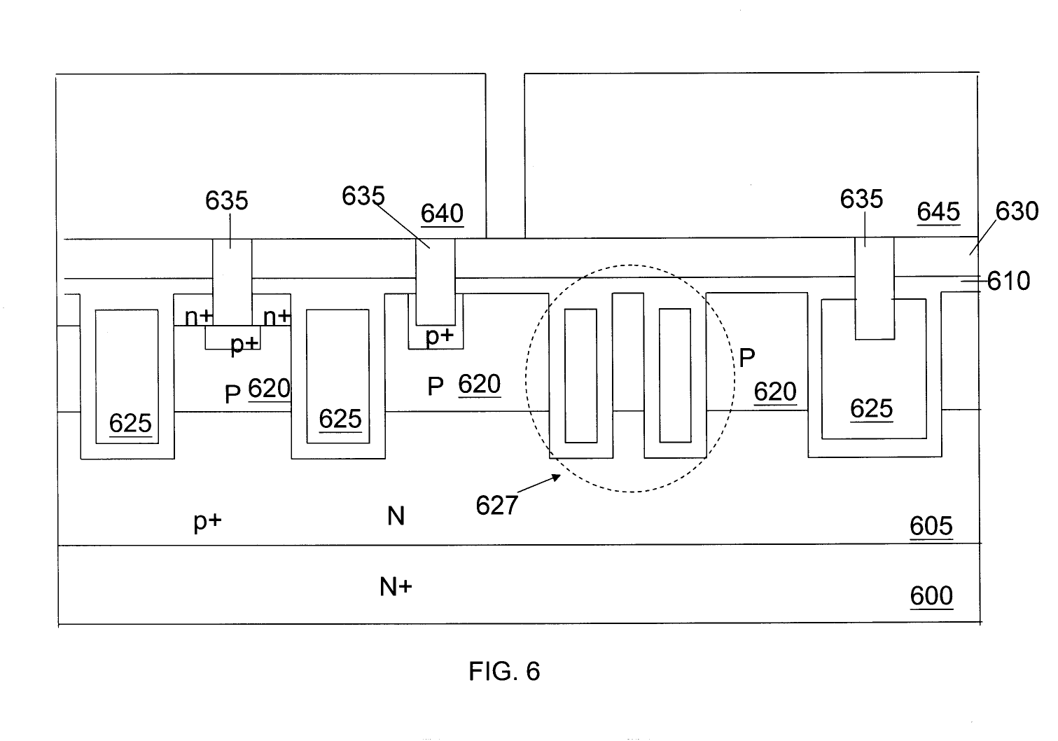

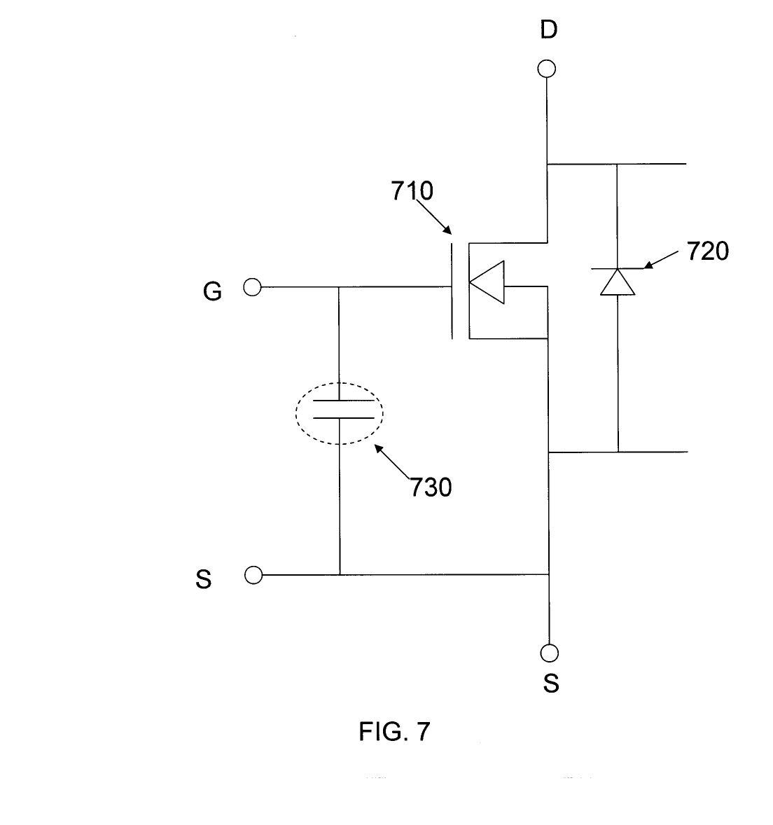

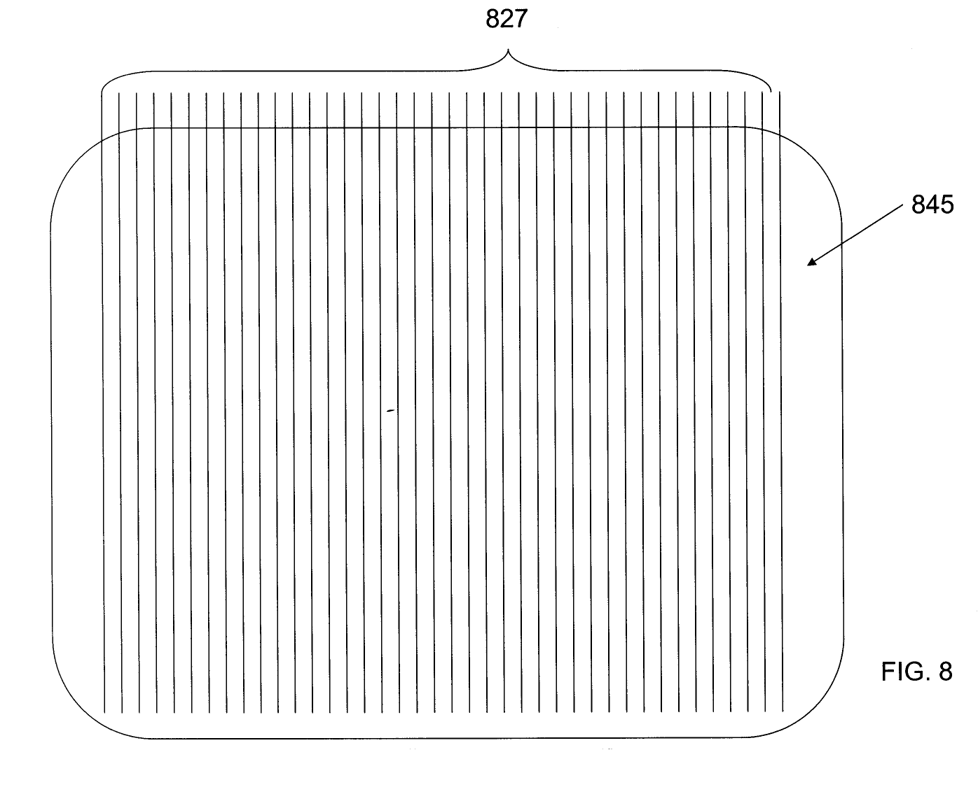

Referring to FIG. 6, a cross-sectional schematic diagram of a first embodiment of the present invention is shown, which depicts a trench MOSFET using a trench capacitor as an ESD element. On a substrate 600, an epitaxial layer 605 is formed by deposition. A plurality of trenches is formed in the epitaxial layer 605 by photolithography and etching. A gate oxide layer 610 is covered on the bottoms and sidewalls of the trenches by thermal growth or deposition, as well as on the epitaxial layer 605. A p-type doping region 620 is then formed in the epitaxial layer 605 at both sides of the trenches by photolithography and ion implantation. Thereafter, n+ doping regions and p+ doping regions are formed in the p-type doping region 620. A gate structure 625 is then filled in the trenches by polysilicon deposition, photolithograph and etching. Finally, metal connections for the trench MOSFET are formed, whereby metal plugs 635 are used to connect the doping regions and the gate structure 625, and a source metal pad 640 and a gate metal pad 645 are used to connect the metal plugs 635. A capacitor structure is formed in the trench (i.e. a trench capacitor 627) using the polysilicon layer of the gate structure 625 as the electrode plates and the oxide layer 610 as the dielectric layer. The trench capacitor and the trench MOSFET are connected via the gate source pad 645 and the source metal pad 640. Referring to FIG. 7, an equivalent circuit diagram of the trench MOSFET of FIG. 6 using a trench capacitor as an ESD element according to the first embodiment of the present invention is shown. At the bottom of a transistor 710, there is a body diode 720. A trench capacitor 730 is connected between the source and gate of the transistor 710. When ESD occurs, electrostatic will propagate from the gate to the source via the capacitor 730, thereby avoiding damage of the transistor 710 as a result of ESD effect. According to an embodiment of the present invention, the larger the area of the electrode plates of the capacitor 730, the more electrostatic can be transferred. According to an embodiment of the present invention, in the trench capacitor structure of FIG. 6, more trenches can be used to form a capacitor, which allows the area of the electrode plate of the capacitor to be larger, thus obtaining a better ESD transfer. Referring to FIG. 8, a planar diagram of the trench MOSFET according to the first embodiment of the present invention is shown. The trenches 827 of the trench capacitor are formed underneath the gate metal pad 845, so as to connect the trench capacitor between the source and the gate.

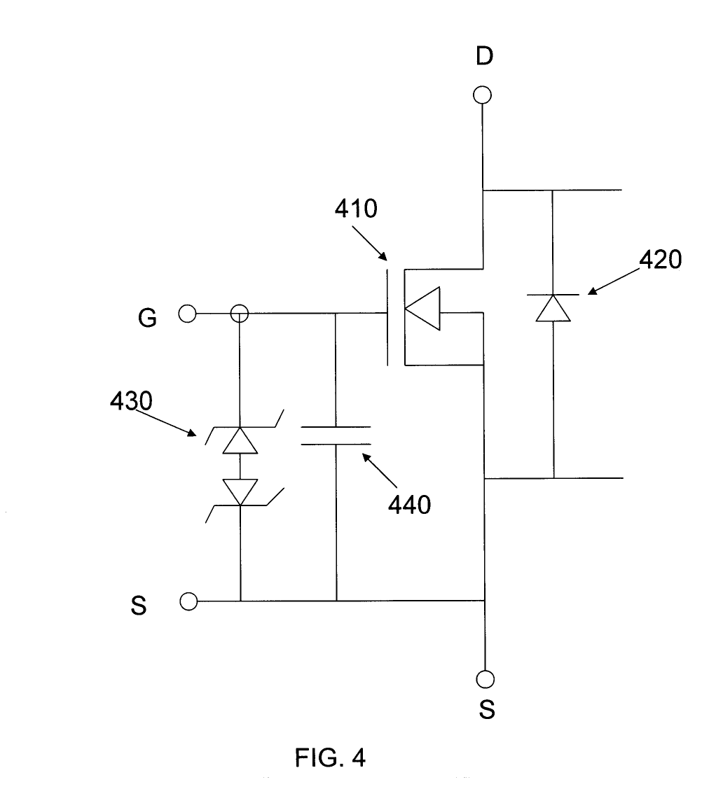

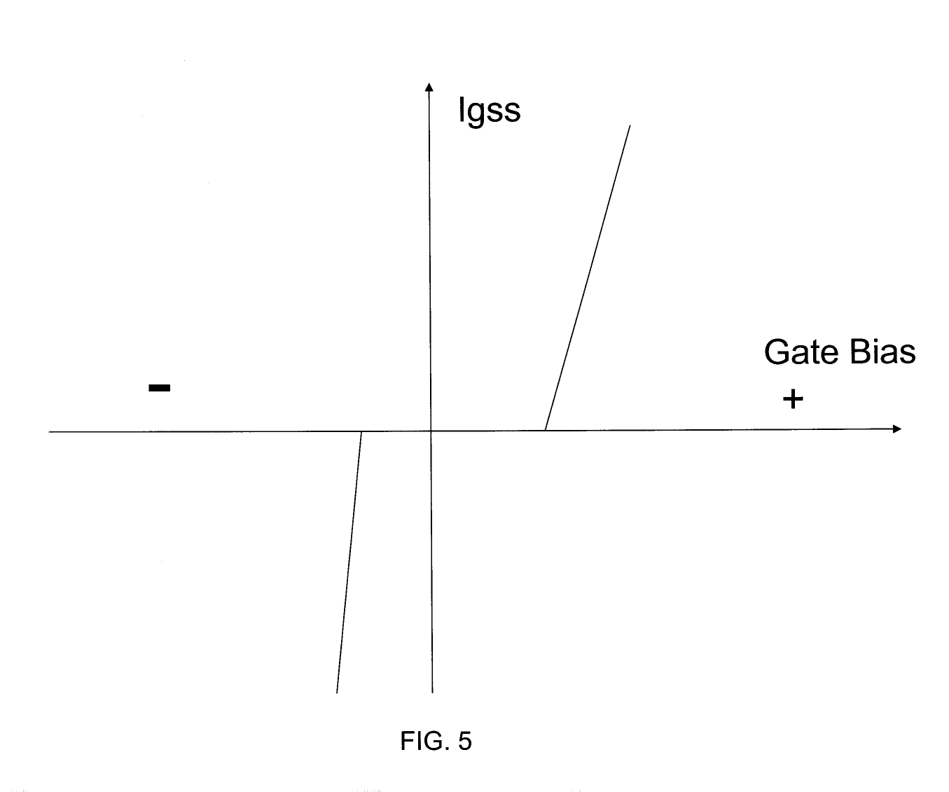

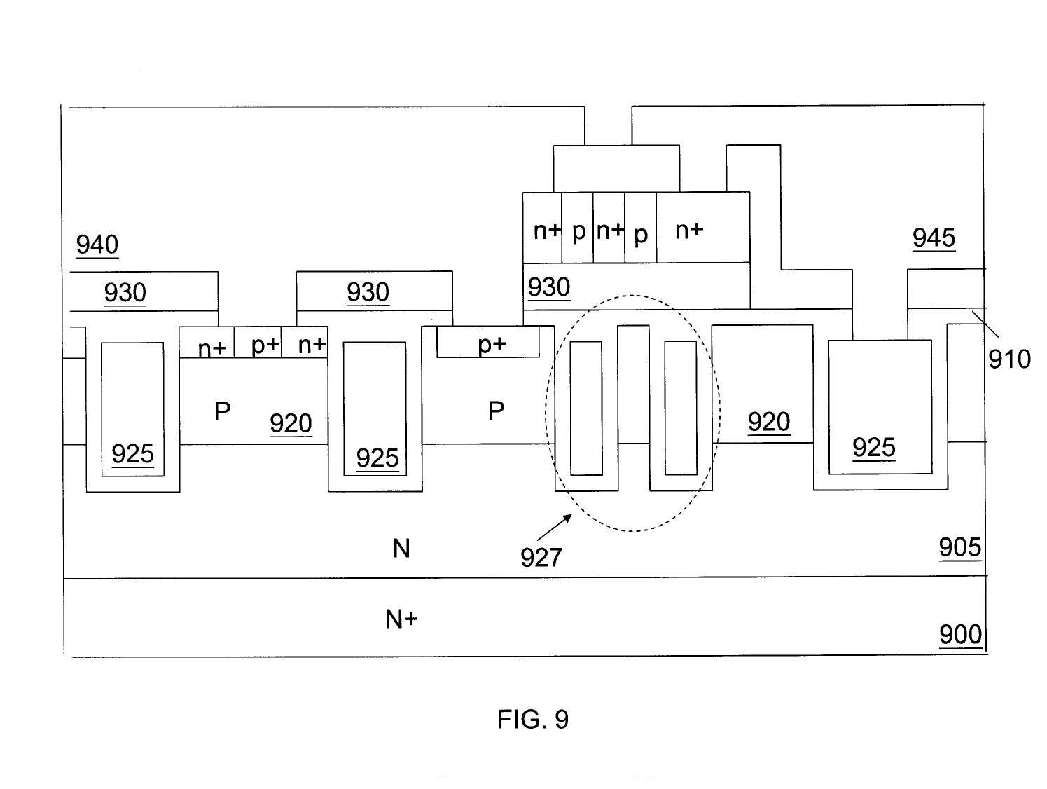

Referring to FIG. 9, a cross-sectional schematic diagram depicting a trench MOSFET using a trench capacitor as the ESD element according to a second embodiment of the present invention is shown. On a substrate 900, an epitaxial layer 905 is formed by deposition. A plurality of trenches is formed in the epitaxial layer 905 by photolithography and etching. An oxide layer 910 is covered on the bottoms and sidewalls of the trenches by deposition, as well as on the epitaxial layer 905. A p-type doping region 920 is then formed in the epitaxial layer 905 at both sides of the trenches by photolithography and ion implantation. Thereafter, n+ doping regions and p+ doping regions are formed in the p-type doping region 920. A gate structure 925 is then filled in the trenches by polysilicon deposition, photolithograph and etching. An insulating layer 930 is then covered on the gate structure 925 and the oxide layer 910. A polysilicon layer is then formed on top of the insulating layer 930 and n+ doping regions and p-type doping region are formed in the polysilicon layer as Zener diode structure by photolithography and ion implantation. Finally, metal connections for the trench MOSFET are formed, whereby a source metal pad 940 and a gate metal pad 945 are used to connect the Zener diode, a trench capacitor 927 and the trench MOSFET. The trench capacitor 927 uses the polysilicon layer of the gate structure 925 as the electrode plates and the oxide layer 910 as the dielectric layer to form a capacitor structure in the trenches. The trench capacitor and the trench MOSFET are connected via the gate source pad 945 and the source metal pad 940. According to the second embodiment of the present invention, the Zener diode is formed on top of the trench capacitor 927. With metal connections, the gate and source of the trench MOSFET are connected via the trench capacitor 927 and the Zener diode. An equivalent circuit diagram of FIG. 9 is the same as that shown in FIG. 4. In the second embodiment of the present invention, the trench capacitor 927 is used as the ESD element having a larger electrode plate area that enhances the ESD effect.

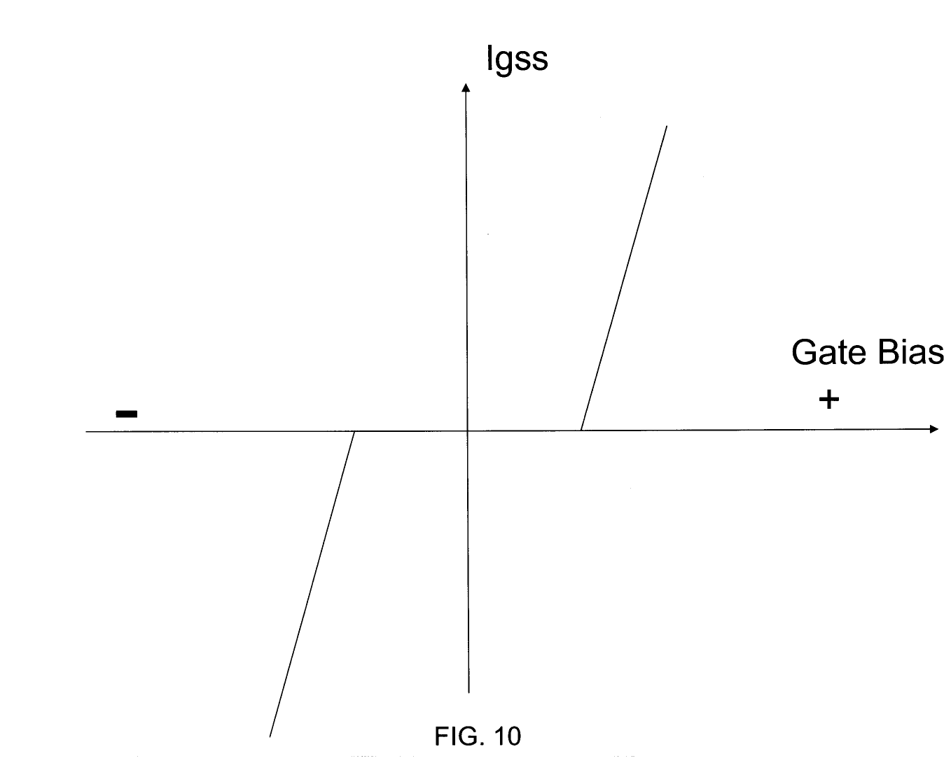

FIG. 10 illustrates current and voltage relationship (Igss versus Gate bias) of the trench MOSFET according to the second embodiment of the present invention. When the thickness of the insulating layer underneath the Zener diode is greater than 1 KA, the channeling effect from the bottom of the p-type doping region can be suppressed, thus realizing a symmetric I-V characteristic.

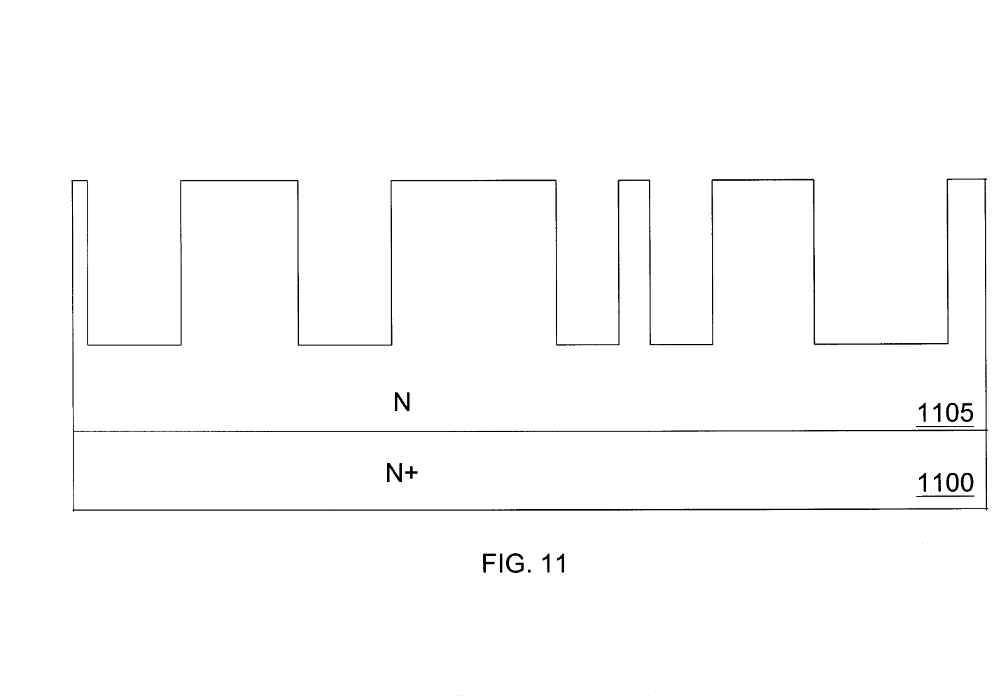

FIGS. 11 to 17 illustrate a process flow for fabricating a trench MOSFET according to a third embodiment of the present invention. Referring to FIG. 11, a semiconductor substrate 1100 is first provided. An epitaxial layer 1105 is then formed on the substrate 1100 via a chemical depositing process. The substrate 1100 is an n+ doping region while the epitaxial layer 1105 is an n-type doping region. Trenches are then formed in the epitaxial layer 1105 by photolithography and etching processes.

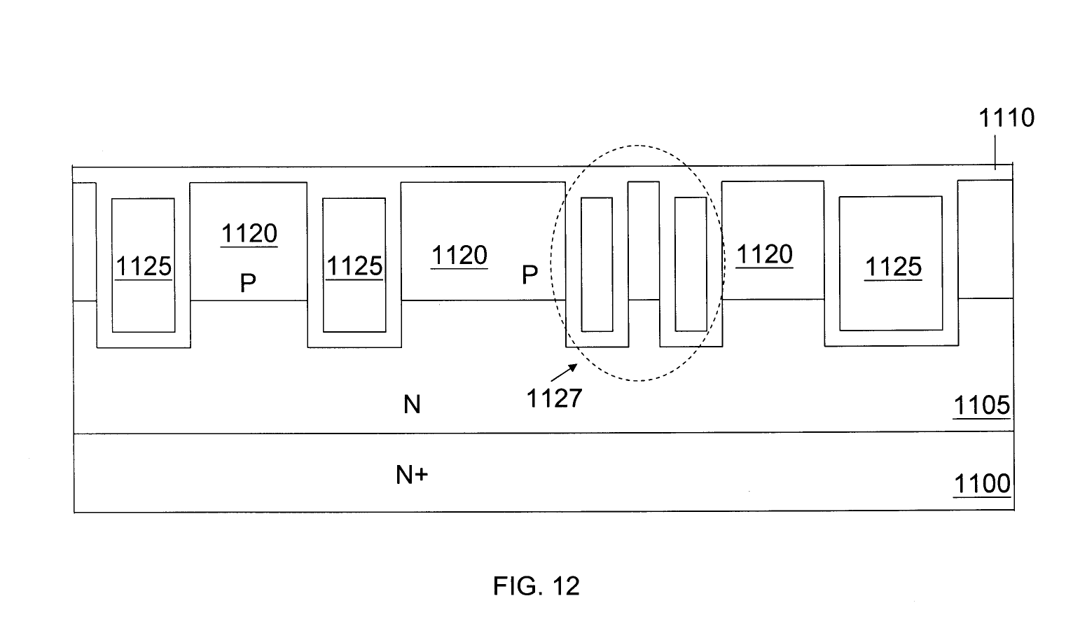

Referring to FIG. 12, an oxide layer 1110 is deposited on the epitaxial layer 1105 covering the bottoms and sidewalls of the trenches. Thereafter, a polysilicon layer is deposited on the oxide layer and filled in the trenches. This polysilicon layer is a polysilicon material doped with impurities. Excess polysilicon material is removed by back etching to form a gate structure 1125 filled in the trenches. While forming the gate structure 1125, the polysilicon layer is also filled into the other trenches to form a capacitor 1127. The capacitor 1127 uses the oxide layer 1110 as the dielectric layer and the polysilicon layer as the electrode plates. Then, a p-type doping region is formed in the epitaxial layer 1105 by ion implantation.

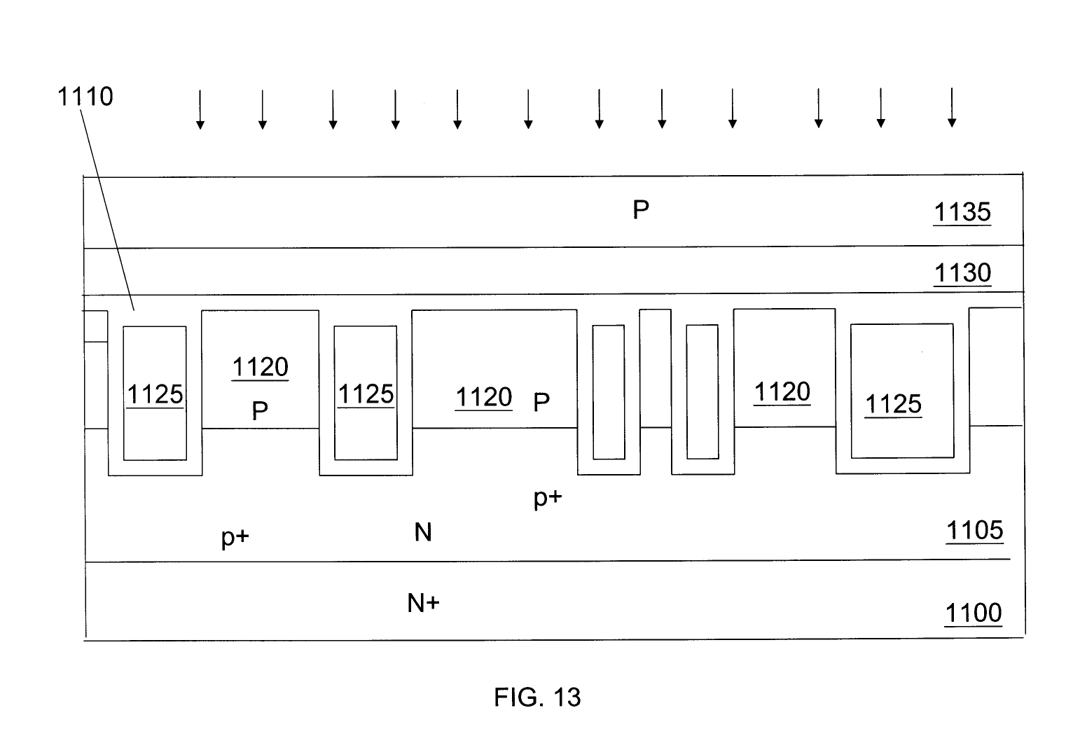

Referring to FIG. 13, a thick oxide layer 1130 with a thickness greater than 1 KA is deposited on the epitaxial layer 1105. Then, another undoped polysilicon layer 1135 is deposited on the thick oxide layer 1130 and boron impurities are doped in to the polysilicon layer 1135 by a full ion implantation process, so the polarity of the polysilicon layer 1135 is positive.

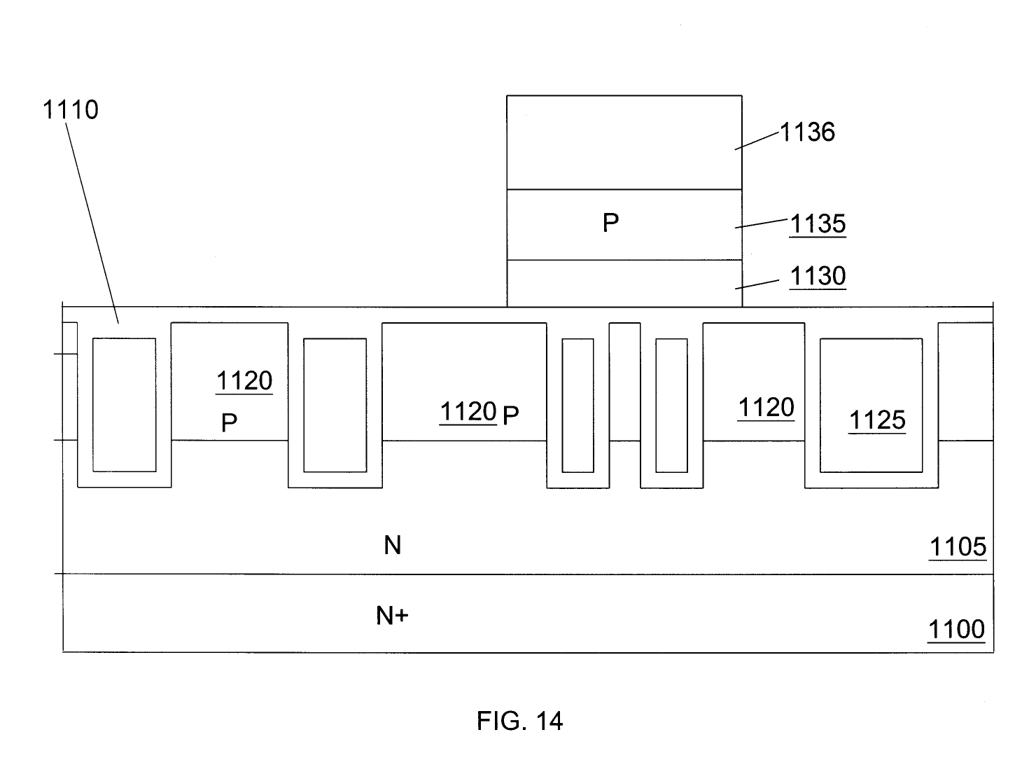

Referring to FIG. 14, a photoresist pattern 1136 is defined on the polysilicon layer 1135 by photolithography, and then the polysilicon layer 1135 and the thick oxide layer 1130 are etched to form a Zener diode structure on the capacitor 1127.

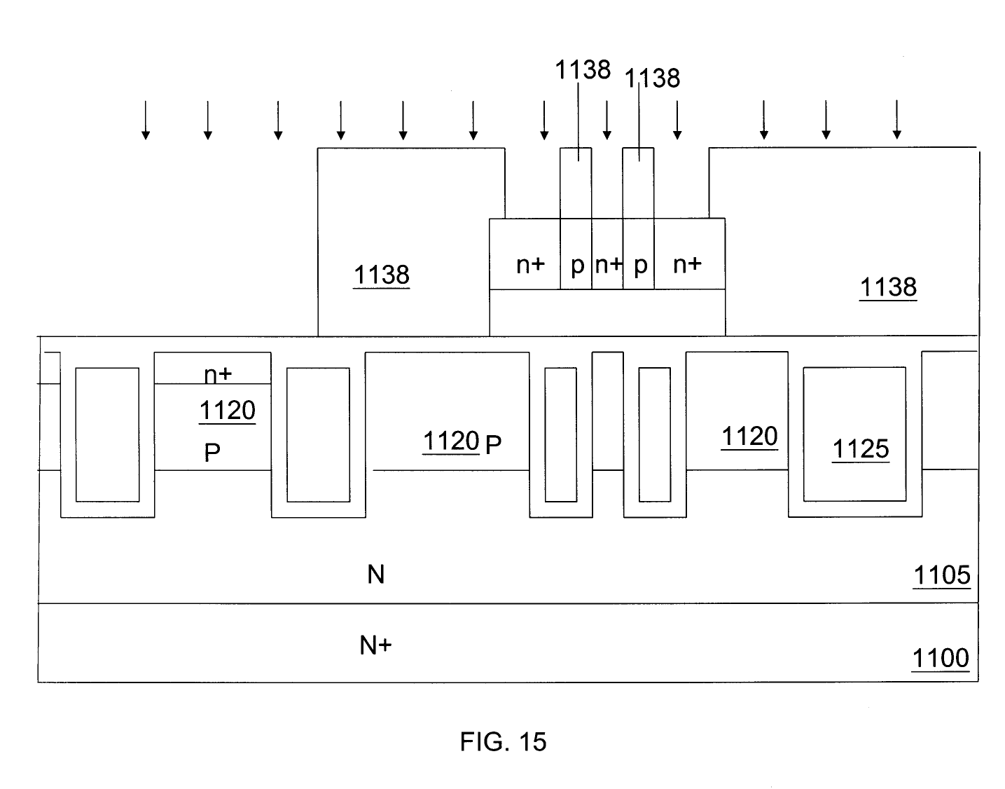

Referring to FIG. 15, another photoresist pattern 1138 is defined by photolithography to expose the intended n-type regions of the Zener diode and the source region of the trench MOSFET, which are then highly doped with arsenic or phosphorous impurities, forming the n+ doping region of the Zener diode and the source region of the trench MOSFET. After the ion implantation, the photoresist pattern 1138 is removed.

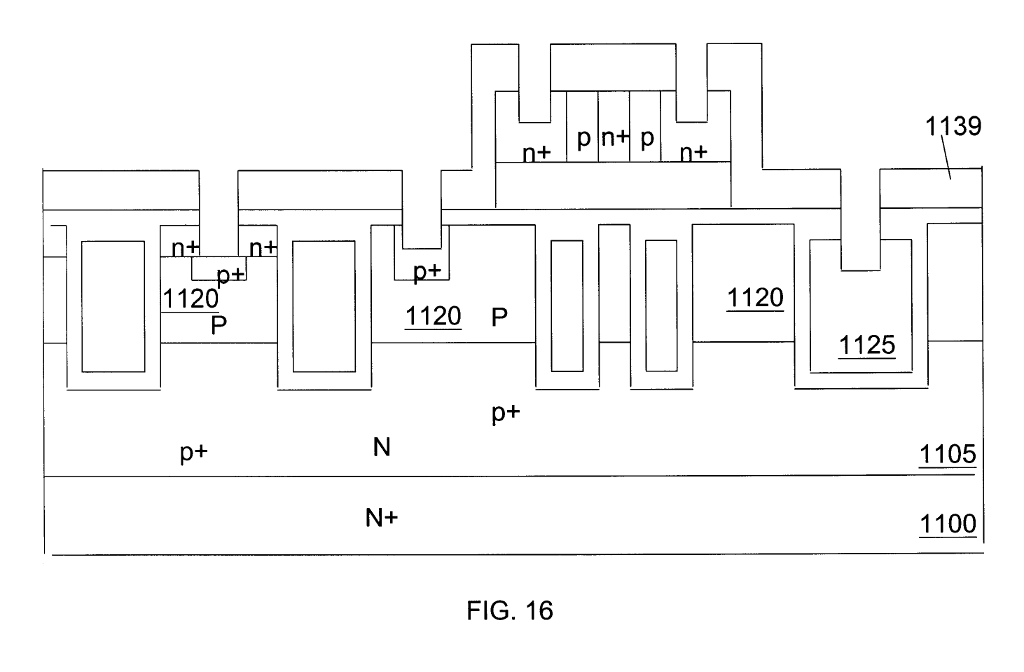

Referring to FIG. 16, an oxide layer 1139 is further formed on the epitaxial layer 1105 by photolithography and etching processes. Contact windows are formed in the oxide layer 1139 to contact the source region of the trench MOSFET and both sides of the Zener diode. Thereafter, photolithography and ion implantation processes are used to dope boron impurities in to the bottom of the contact windows of the source region to form p+ highly doped regions.

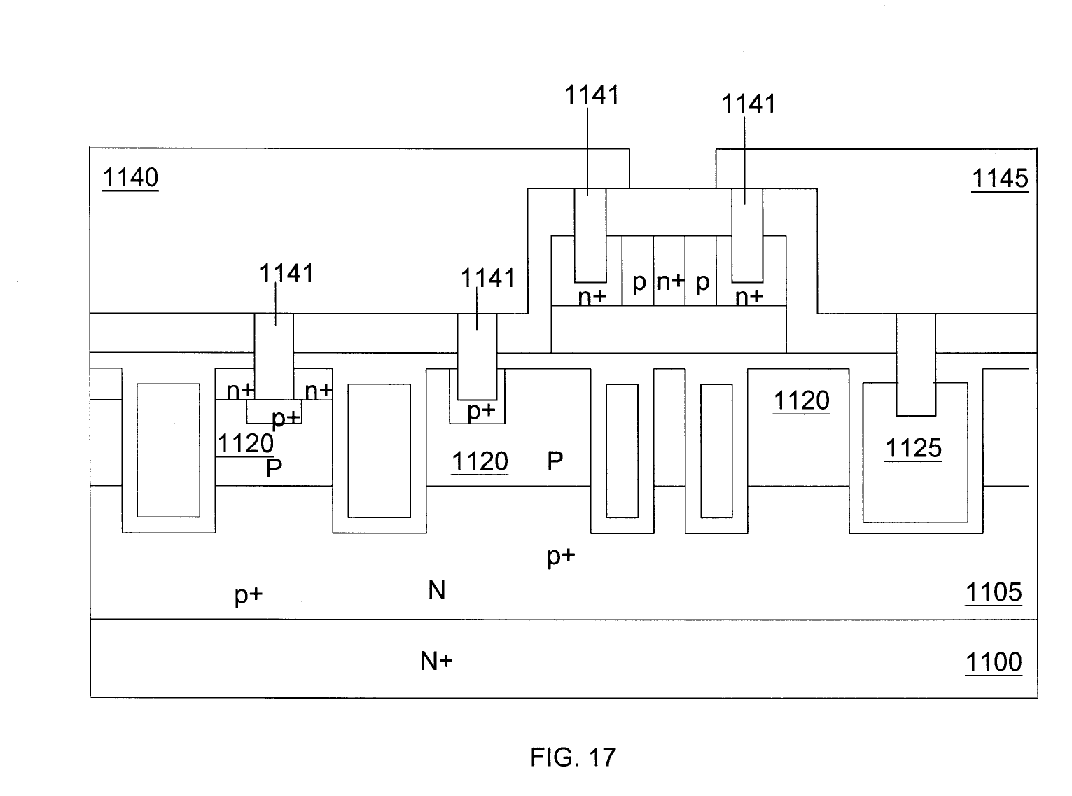

Referring to FIG. 17, a metal material is filled back into the contact windows, forming metal plugs 1141. Then, deposition and etching processes are used to form a source metal pad 1140 and a gate metal pad 1145 contacting the metal plugs 1141, thus completing the metal connections for the trench MOSFET, the capacitor 1127 and the Zener diode. According to an embodiment of the present invention, the metal plugs 1141 are formed by sequentially depositing Ti metal, TiN material and Tungsten metal. Tungsten metal is back etched to form the metal plugs 1141 in the contact windows.

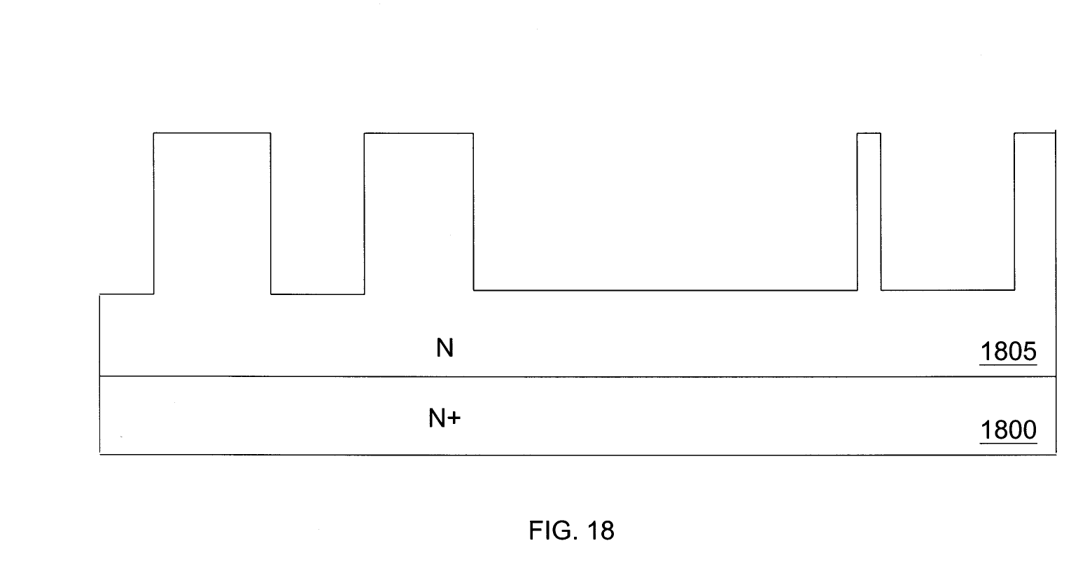

Referring to FIGS. 18 to 24, the process flow according to a fourth embodiment of the present invention is shown. Referring to FIG. 18, an epitaxial layer 1805 is formed on a substrate 1800 via a chemical depositing process. The substrate 1800 has an n-type doping polarity while the epitaxial layer 1805 has an n+ doping region. Trenches are then formed in the epitaxial layer 1805 by photolithography and etching processes. These trenches are used as structures of the trench MOSFET and a trench capacitor. The trenches in the trench capacitor exhibit a larger width, thus the capacitor has a larger capacitor area, so the ESD effect is enhanced.

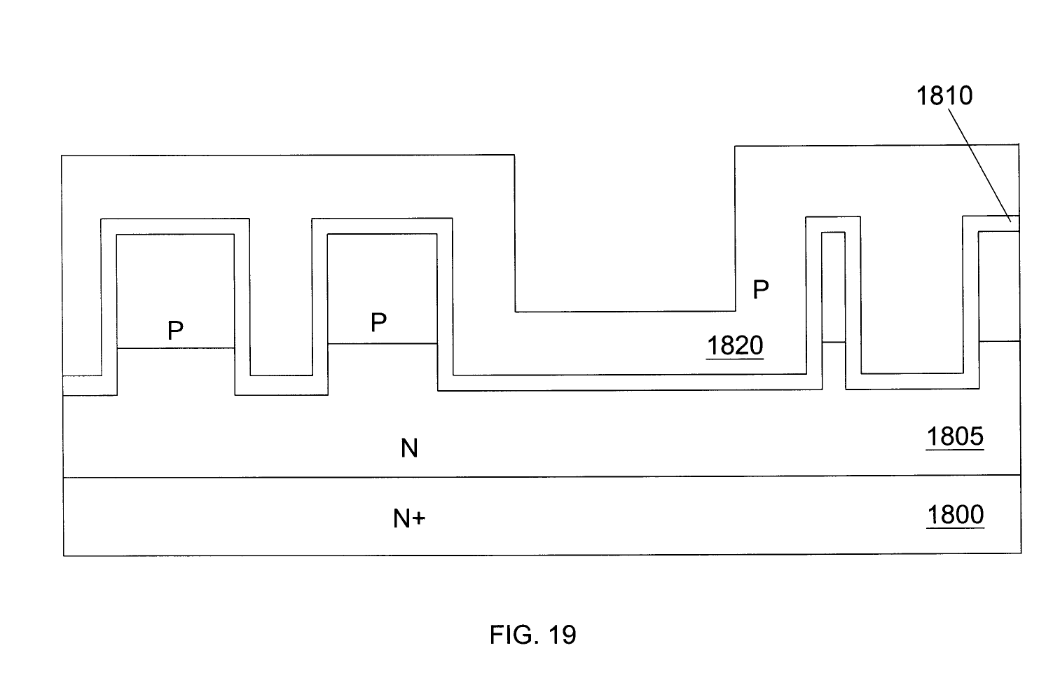

Referring to FIG. 19, an oxide layer 1810 is deposited on the epitaxial layer 1805 covering the bottoms and sidewalls of the trenches. After forming the oxide layer 1810, p-type regions are formed in the epitaxial layer 1805 by ion implantation. A polysilicon layer 1820 is then deposited on the oxide layer 1810. This polysilicon layer is a polysilicon material doped with impurities.

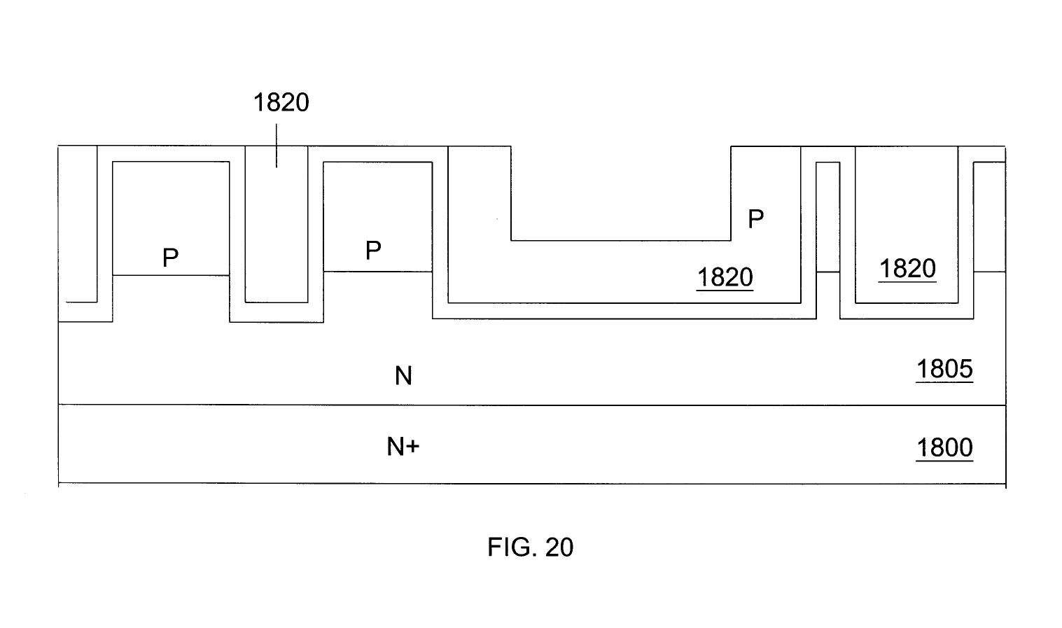

Referring to FIG. 20, excess polysilicon layer 1820 is removed by chemical mechanical polishing (CMP) process to form a gate structure and electrode plates of the capacitor in the trenches (polysilicon layer 1820 in FIG. 20).

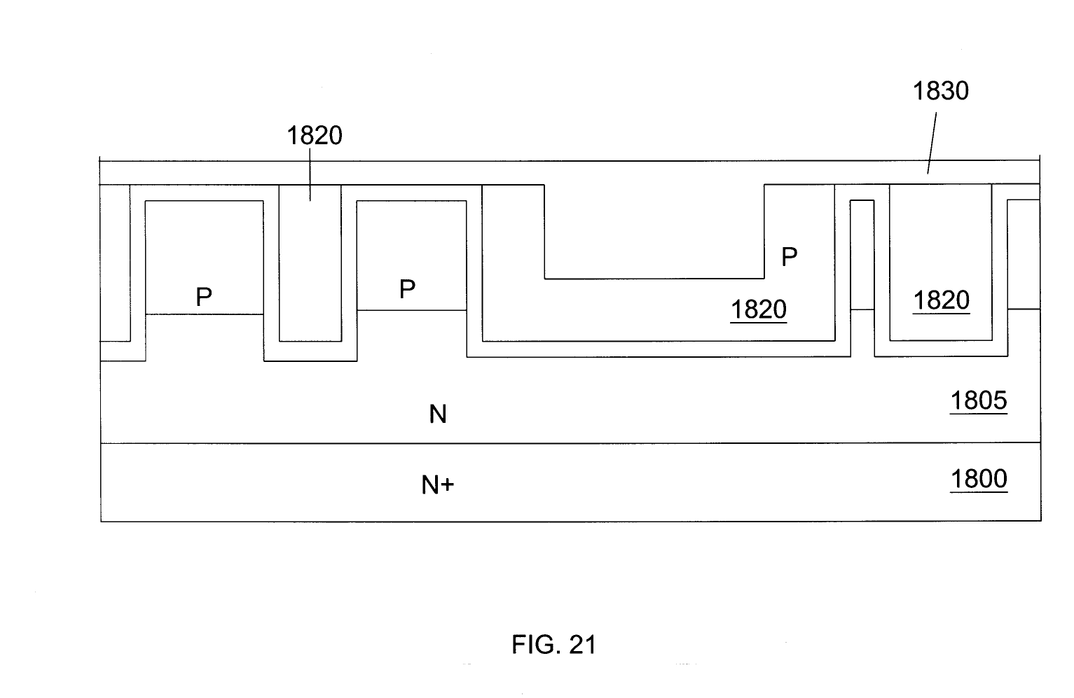

Referring to FIG. 21, an oxide layer 1830 is deposited on the epitaxial layer 1805, covering the polysilicon layer 1820, then planarized by the CMP process.

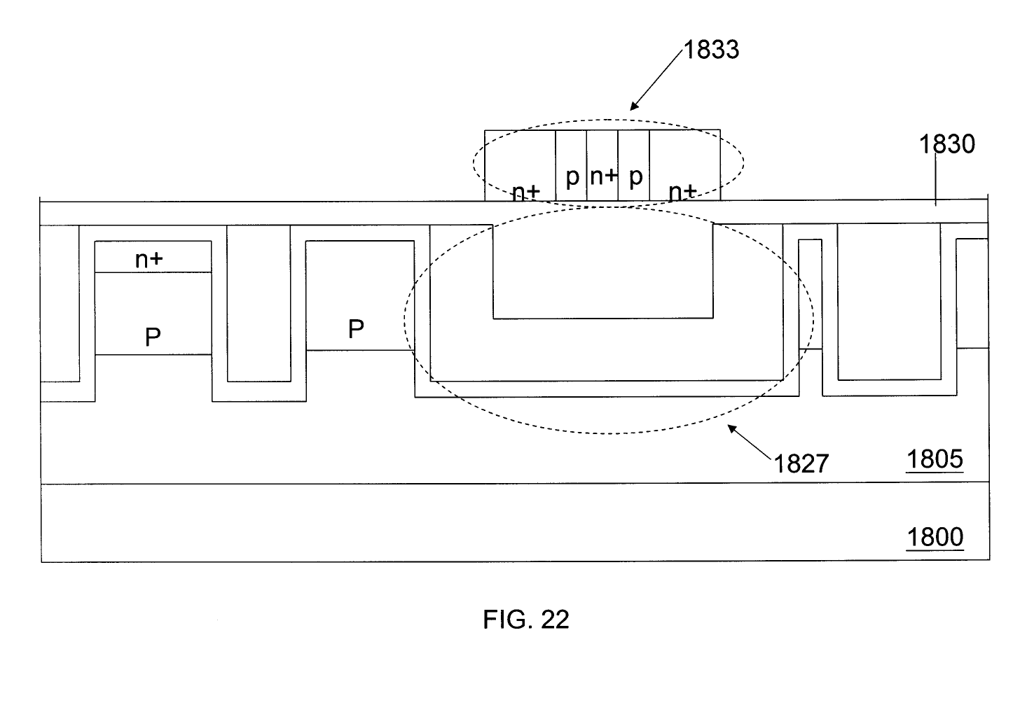

Referring to FIG. 22, structure of a Zener diode 1833 is formed on the capacitor 1827 by deposition and photolithography and etching processes. This structure is made of a p-type doped polysilicon material. Then, n+ doping regions are formed on the main structure of the Zener diode 1833 via an ion implantation process. Meanwhile, an n+ doping region is also formed in the p-type doping region of the epitaxial layer 1805 to be used as the source region of the trench MOSFET.

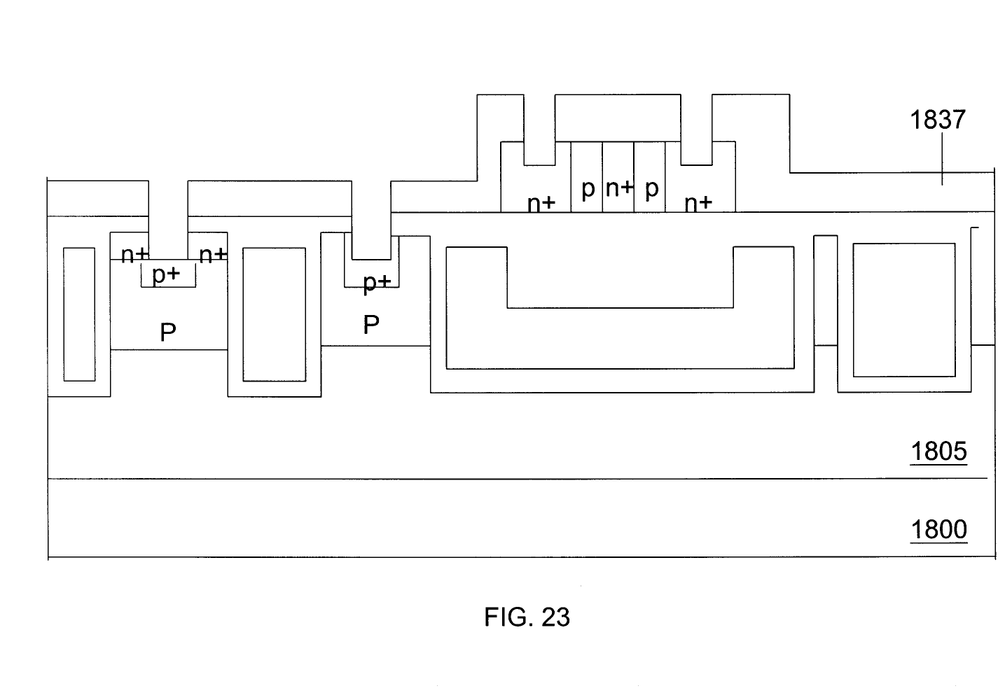

Referring to FIG. 23, an insulating layer 1837 is covered on the epitaxial layer 1805. Source contact windows of the trench MOSFET and the contact windows of the Zener diode 1833 are formed in the insulating layer 1837 via photolithography and etching processes. In addition, p+ doping regions are formed on the bottoms of the source contact windows.

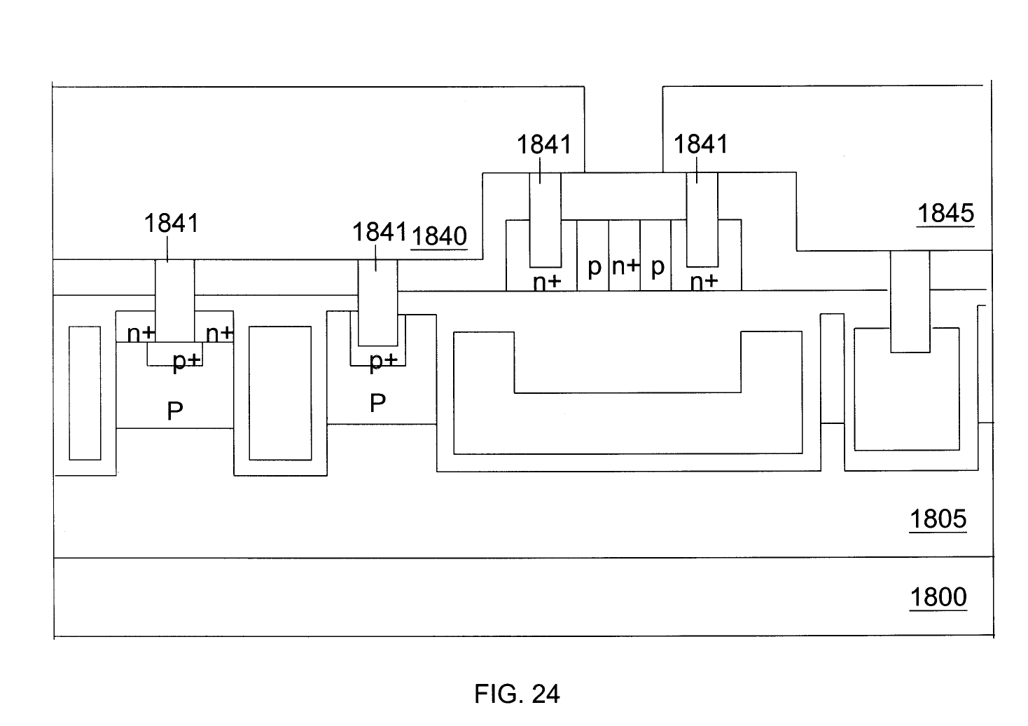

Referring to FIG. 24, a metal material is filled back into the contact windows, forming metal plugs 1841. Then, deposition and etching processes are used to form a source metal pad 1840 and a gate metal pad 1845 contacting the metal plugs 1841, thus completing the metal connections for the trench MOSFET, the capacitor 1827 and the Zener diode 1833. According to an embodiment of the present invention, the metal plugs 1141 are formed by sequentially depositing Ti metal, TiN material and Tungsten metal. Tungsten metal is back etched to form the metal plugs 1841 in the contact windows.

According to an embodiment of the present invention, the trench capacitor in the trench MOSFET acts as an ESD element. The larger the area of the electrode plates of the capacitor, the better the discharge. A plurality of trenches may form a single capacitor, thus increasing the area of the electrode plates of the capacitor.

According to an embodiment of the present invention, the Zener diode in the trench MOSFET acts as an ESD element. The Zener diode consists of a plurality of n+ doping regions and p+ doping regions, which may be a combination of “n+/p/n+/p/n+” or a combined structure with more doping regions, e.g. n+/p/n+/p/n+/p/n+.

Although various embodiments are specifically illustrated and described herein, it will be appreciated that modifications and variations of the present invention are covered by the above teachings and are within the purview of the appended claims without departing from the spirit and intended scope of the invention.

What is claimed is:

1. An electrostatic discharging (ESD) protected metal oxide semiconductor field effect transistor (MOSFET), comprising:
an epitaxial layer on substrate;
a trench gate structure formed in the epitaxial layer;
a body and source regions formed in the epitaxial layer surrounding the gate structure in active area; and
a trench capacitor formed underneath gate metal pad in the epitaxial layer connected between the source region and the gate structure,
wherein the trench capacitor acts as an ESD improved element for the MOSFET.

2. The MOSFET of claim 1, further comprising a polysilicon Zener diode formed on the epitaxial layer and connected between the source region and the gate structure.

3. The MOSFET of claim 2, wherein the Zener diode is disposed on the trench capacitor, sandwiched with a thick oxide with thickness greater than 1 KA.

4. The MOSFET of claim 2, wherein when an electrostatic voltage is larger than a breakdown voltage of the Zener diode, the Zener diode passes the electrostatic charge from a gate to a source of the MOSFET.

5. The MOSFET of claim 2, wherein the Zener diode consists of a plurality of doping regions with alternative n+/P+ polarities.

6. The MOSFET of claim 2, wherein inner metal connections are used to connect the Zener diode, the source region and the trench gate structure.

7. The MOSFET of claim 6, wherein the inner metal connections realize metal contacts for the Zener diode, the source region and the trench gate structure by metal plugs.

8. The MOSFET of claim 1, wherein the trench capacitor comprises a plurality of trench structures.

9. The MOSFET of claim 1, wherein the larger the area of electrode plates of the trench capacitor, the better the effect of ESD.

10. The MOSFET of claim 9, wherein the larger the area of the trench capacitor, the larger the area of electrode plates of the capacitor.

11. A method for fabricating an ESD protected MOSFET, comprising:
forming trenches in a epitaxial layer;
forming a body and source regions in the epitaxial layer at both sides of the trenches in active area;
forming an oxide layer covering the epitaxial layer and the trenches;
forming a doped polysilicon layer on the oxide layer and filling the trenches;
removing the polysilicon layer that are on top of the epitaxial layer to form a trench gate structure and a trench capacitor, wherein the oxide layer acts as a gate oxide layer of the gate structure and the dielectric layer of the trench capacitor;
forming an insulating layer on the epitaxial layer, the trench capacitor and the trench gate structure;
forming an undoped polysilicon layer on the trench capacitor;
forming a Zener diode on the polysilicon layer; and
forming metal connections for connecting the Zener diode and the capacitor between the trench gate structure and the source region.

12. The method of claim 11, wherein the trench capacitor comprises a plurality of trench structures.

13. The method of claim 11, wherein the larger the area of electrode plates of the trench capacitor, the better the effect of ESD.

14. The method of claim 13, wherein the larger the area of the trench capacitor, the larger the area of electrode plates of the capacitor.

15. The MOSFET of claim 11, wherein when an electrostatic voltage is larger than a breakdown voltage of the Zener diode, the Zener diode passes the electrostatic charge from a gate to a source of the MOSFET.

16. The method of claim 11, wherein the Zener diode consists of a plurality of doping regions with alternative n+/P+ polarities.

17. The method of claim 11, wherein inner metal connections are used to connect the Zener diode, the source region and the trench gate structure.

18. The method of claim 17, wherein the inner metal connections realize metal contacts for the Zener diode, the source region and the trench gate structure by metal plugs.
